(19) United States
(12) Patent Application Publication
(10) Pub. No.: US 2013/0105421 A1
(43) Pub. Date: May 2, 2013

(54) Repeatable hangers and precision repeatable magnet mounting

(71) Applicant: Alex K. Deyhim, Ithaca, NY (US)

(72) Inventor: Alex K. Deyhim, Ithaca, NY (US)

(21) Appl. No.: 13/317,705

(22) Filed: Oct. 26, 2011

(51) Int. Cl. H05K 7/18; H05B 1/00

(52) U.S. Cl. 211/26; 219/494

(57) ABSTRACT

A system of outer supports for in vacuum girders driven by two lead screws, supported at the approximate quarter points and a second set of less massive in vacuum girders. The embodiment of the design is comprised of two spherical joints, outer holds bellows, inner threads into the girder, and split coupling. This invention makes changing bellows easier, allowing for bellow replacement without disturbing magnet shimming. This system provides the overall rigidity necessary to maintain the required straightness and flatness of the magnet modules over a range of magnet gaps and varying attractive magnetic forces.

### CROSS REFERENCE TO RELATED APPLICATIONS

Not applicable

### STATEMENT REGARDING FEDERALLY SPONSORED RESEARCH OR DEVELOPMENT

Not Applicable

### SEQUENCE LISTING OR PROGRAM

Not Applicable

### BACKGROUND OF THE INVENTION

An undulator is an insertion device from high-energy physics and usually part of a larger installation; a synchrotron storage ring consisting of a periodic structure of dipole magnets. The static magnetic field alternates along the length of the undulator with a wavelength of λ⁴. Electrons traversing the periodic magnet structure are forced to undergo oscillations and thus to radiate energy.

The radiation produced in an undulator is very intense and concentrated in narrow energy bands in the spectrum. It is also collimated on the orbit plane of the electrons. This radiation is guided through beamlines, lines in a linear accelerator along which a beam of particles travel, for experiments in various scientific areas including particle acceleration, synchrotron radiation and neutron scattering.

Undulators can provide several orders of magnitude higher flux than a simple bending magnet and as such are in high demand at synchrotron radiation facilities. For an undulator with N periods, the brightness can be up to N² more than a bending magnet. The intensity is enhanced up to a factor of N at harmonic wavelengths due to the constructive interference of the fields emitted during the N radiation periods.

When an in-vacuum, cryo-cooled undulator or any type of undulator for that matter, mounted in a vacuum chamber is designed and built, it is normal to shim the device, collect data and adjust the homogeneity of the magnetic field, then decouple the magnet array, mount the chamber and then slide the magnets inside the chamber. When doing this there is always the question as to whether or not the magnet returned to its original position, defeating the purpose of shimming in the first place.

### SUMMARY OF THE INVENTION

For in-vacuum girders, with the required structural rigidity for the UHV magnet arrays, an impractically large vacuum vessel is required. Therefore it is necessary to break up the magnet support girders in two parts, for the sake of ease. A system of two very rigid outer support girders each driven by two lead screws, supported at the approximate quarter points and a second set of less massive in vacuum girders, were devised. Between the out-of-vacuum and in-vacuum girders, are a system of eight rigidly affixed stainless steel posts. This system provides the overall rigidity necessary to maintain the required straightness and flatness of the magnet modules over a range of magnet gaps and varying attractive magnetic forces.

Temperature fluctuations in the environment surrounding the in-vacuum magnet components have the potential to result in unacceptable gap distortion. Furthermore, the distortions could not be detected using conventional means. The magnet gap is controlled using a pair of precision re-circulating ball nut lead screws driven by stepper motors. Position feedback is provided by precision linear encoders mounted to the outer girders.

Environmentally induced changes that may occur between the outer girder and the magnet gap could not be detected by the internally mounted linear encoders, thus exteriorly mounted encoders are necessary. In this invention, a mechanical design has been developed that allows very repeatable magnet array mounting and demounting within an undulator system. The design is comprised of two spherical joints, outer holds bellows, inner threads into the girder, and split coupling. This invention makes changing bellows easier, allowing for bellow replacement without disturbing magnet shimming.

### BRIEF DESCRIPTION OF DRAWINGS

The invention as described herein with references to subsequent drawings, contains similar reference characters intended to designate like elements throughout the depictions and several views of the depictions. It is understood that in some cases, various aspects and views of the invention may be exaggerated or blown up (enlarged) in order to facilitate a common understanding of the invention and its associated parts.

FIG. 1 shows the two spherical joints.

FIG. 2 shows the hanger assembly.

FIG. 3 shows the internal girder supports.

FIG. 4 shows a platten support rod.

FIG. 5 shows the end magnet subassembly.

FIG. 6 shows the magnet holder, type 1.

FIG. 7 shows the magnet holder, type 2.

FIG. 8 shows the magnet holders assembly.

FIG. 9 shows the magnet holders assembly, top view.

FIG. 10 shows the machined in magnet holder.

FIG. 11 shows the machined in magnet holder, close up.

FIG. 12 shows the dowel pin holes.

FIG. 13 shows the in vacuum girder.

FIG. 14 shows a platten support assembly

FIG. 15 shows the overall mechanical vacuum girder design.

### DETAILED DESCRIPTION OF INVENTION

Provided herein is a detailed description of one embodiment of the invention. It is to be understood, however, that the present invention may be embodied with various dimensions. Therefore, specific details enclosed herein are not to be interpreted as limiting, but rather as a basis for the claims and as a representative basis for teaching one skilled in the art to employ the present invention in virtually any appropriately detailed system, structure, or manner.

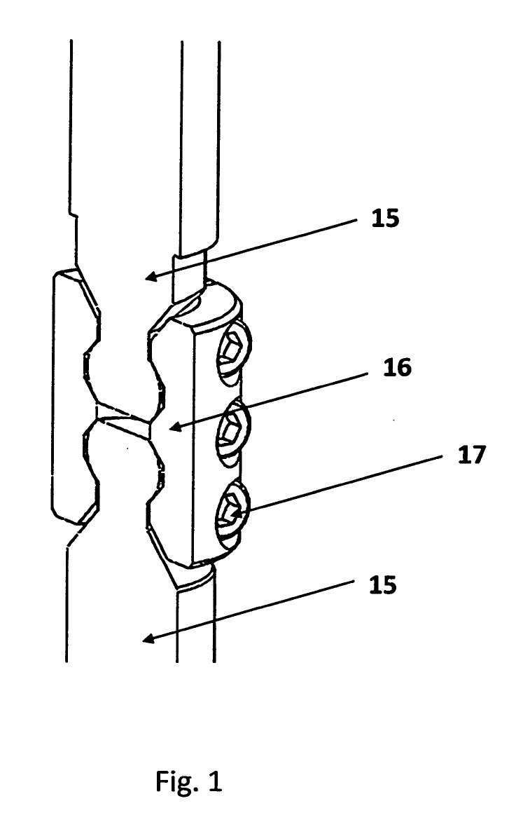

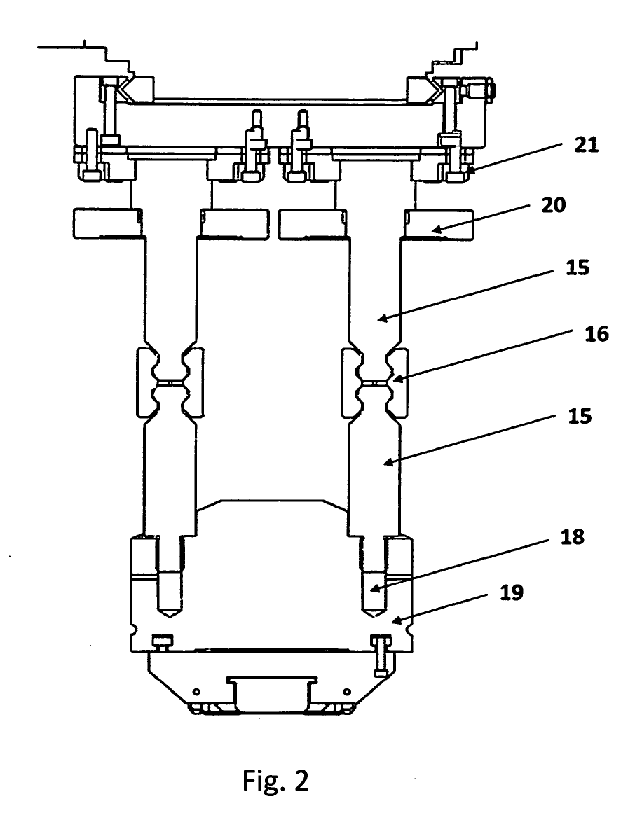

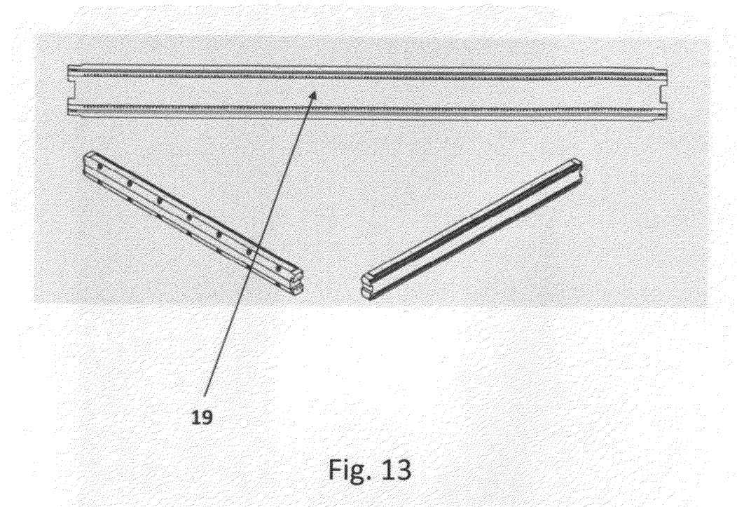

FIG. 1 shows the spherical joint as incorporated as one portion of the invention. The joint consists of two hanger rods 15 with rounded ‘heads’ for a tight fit within the hanger rod collar 16. The two rods are secured within the collar using torque coupling screws 17. The spherical joint is incorporated in the entire hanger assembly which is seen in FIG. 2. Rod couplings, referred here as hanger rod collars 16, allow for movement/separation of the hanger rods 15 for ease of replacement of bellows without disturbing magnet shimming. Also seen in FIG. 2 are the rods that thread into the girder 18, the in vacuum girder 19, seen in FIG. 13, hanger mount disks 21 and CF flange 20, which is comprised of a copper gasket and knife edge flange in order to achieve an ultra-high vacuum seal.

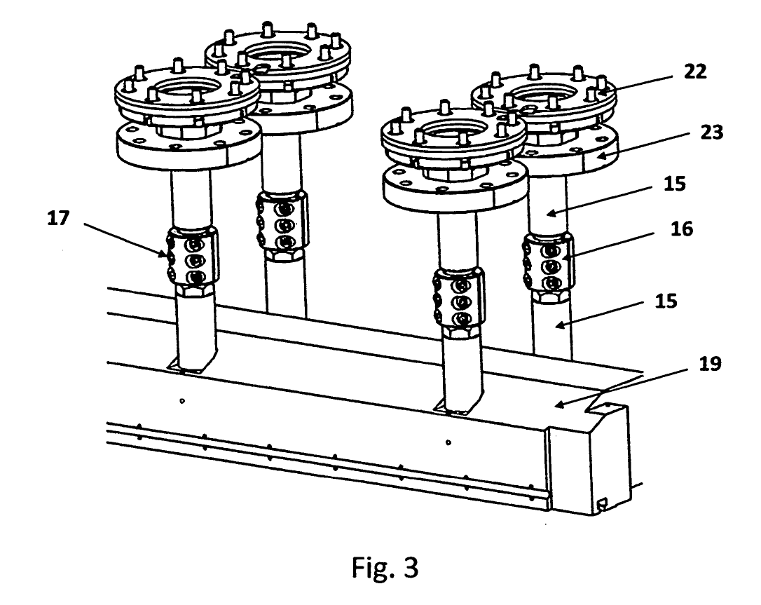

FIG. 3 is a depiction of the internal support girders. Illustrated parts include the in vacuum girder 19, hanger rods 15 and collars 16, as previously mentioned, as well as torque coupling screws 17. Also included are the hanger shims 22 and hanger rod weldment 23.

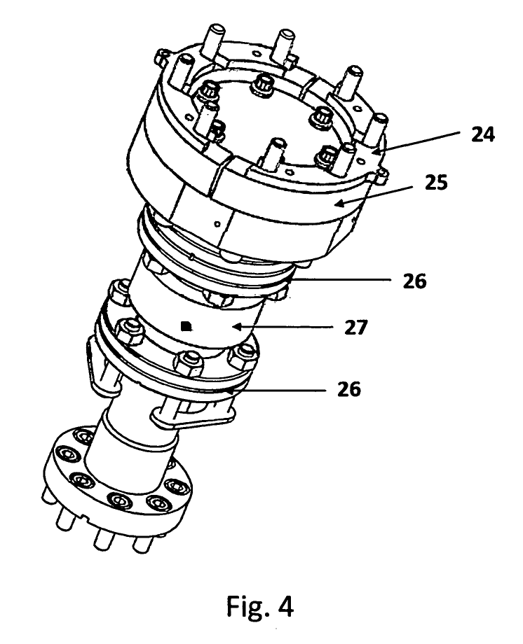

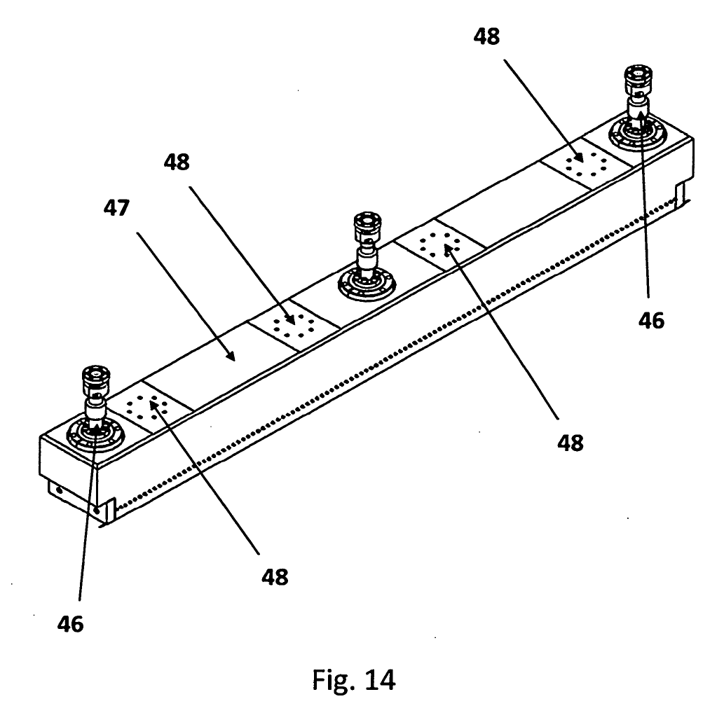

FIG. 4 shows the platten support rod, comprising hanger heaters as a component of the platten support assembly seen in FIG. 14. The support rod, comprising hanger heater components for use in the overall design to maintain a desired temperature to account for external environmental changes, in FIG. 4 is comprised of the split ring shim 24, split ring half 25, copper gaskets 26, and girder support rod 27. This rod is placed within the platten support assembly as a means of stability. FIG. 14 shows the entire assembly, as labeled magnet platten 47, complete with support rods 48, and ball screws.

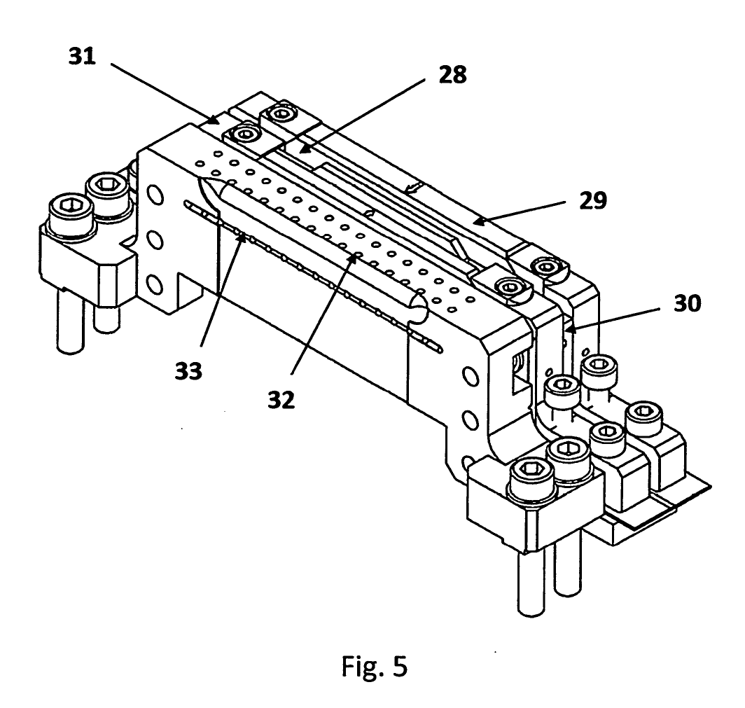

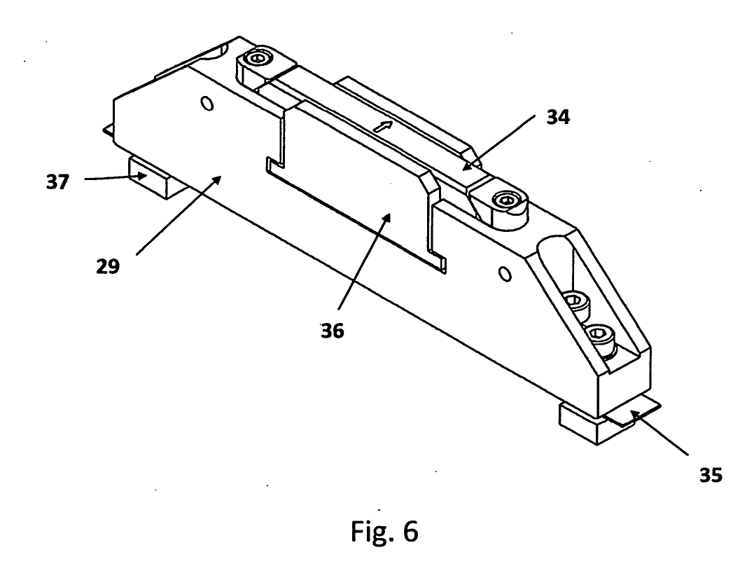

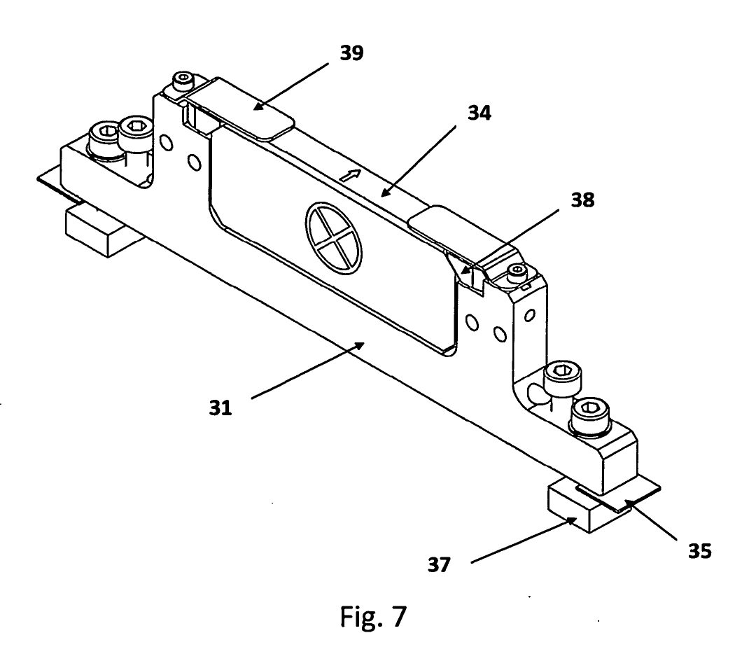

The next component is the end magnet subassembly, seen in FIG. 5. This is the grouping of magnets, which can range from very few to many, depending on need and requirement, as they appear at the end of the magnet line. The subassembly is comprised of the magic finger holder block 32 which holds the corrector magnets to maintain alignment and charge for the overall magnet assembly, magic finger magnet spacer 33, which keeps space between corrector magnets, end magnet holder type 2, 31, end magnet holder type 1, 29, end magnet spacer plate 30, for maintaining distance between magnets within holders, and end magnet pole 28. FIG. 6 is a schematic of the end magnet holder type 1, 29. Important components include the magnet block 34, magnet pole 36, adjustment shim 35 and positioning nut 37. FIG. 7 is a schematic of the end magnet holder type 2, 31, with magnet block 34, magnet clamp 38, foil clamp 39, adjustment shim 35 and positioning nut 37.

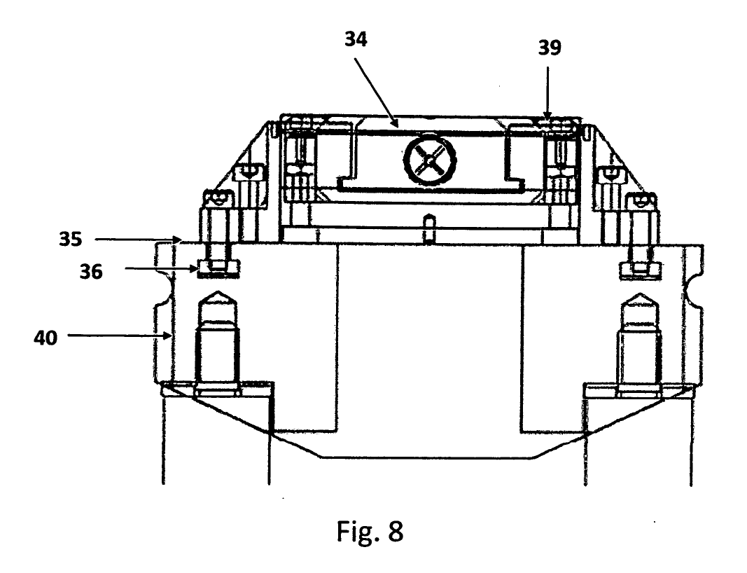

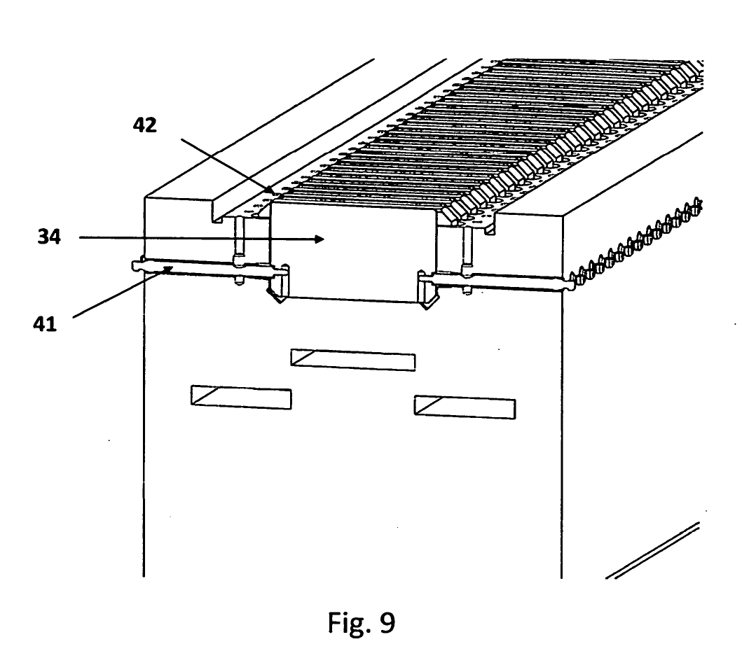

FIG. 8 is the magnet holder assembly as it appears when it is attached to the girder 40. Parts include the magnet block 34, foil clamp 39, adjustment shim 35 and positioning nut 37. FIG. 9 is the top view of the magnet holder assembly with view of the magnet block 34, magnet holders 42 and retention pin 41, which hold each individual magnet in place.

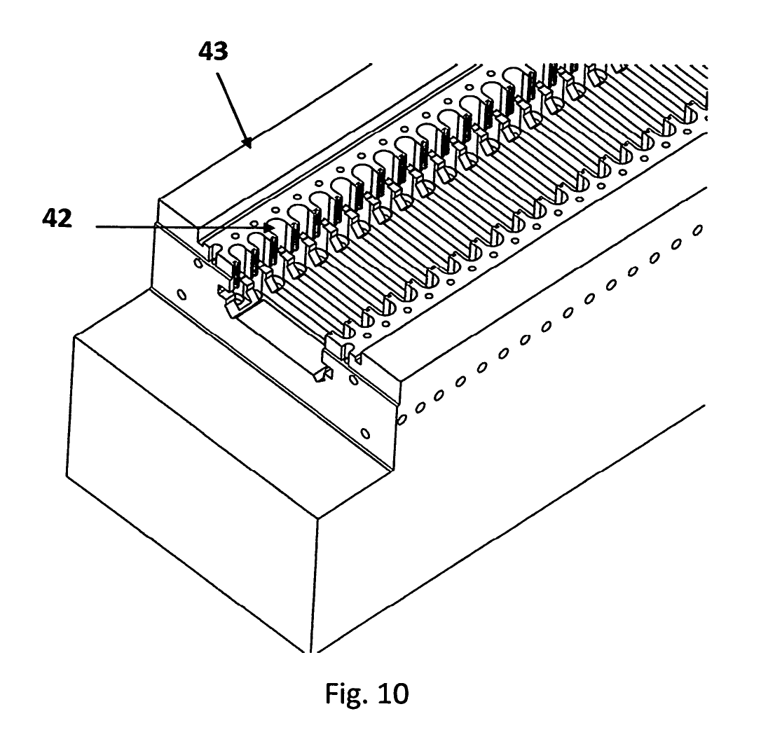

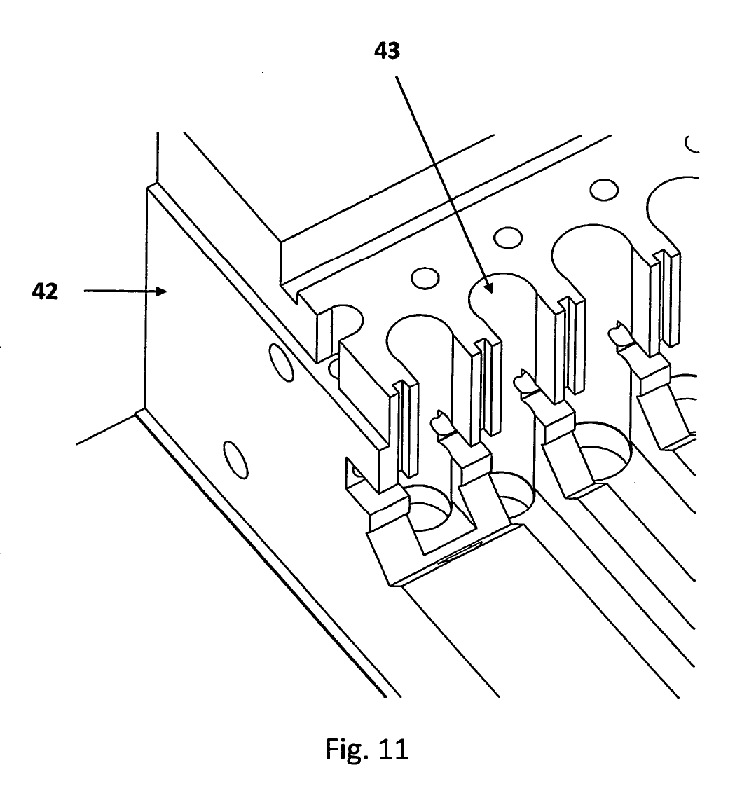

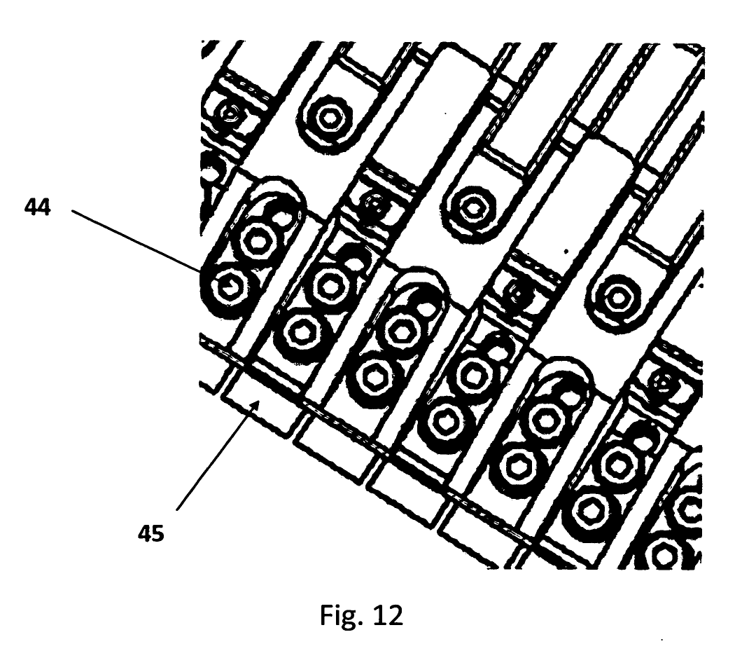

FIG. 10 is the machined in magnet holder. Magnets are held in a machined and stir-welded, monolithic holder 43, providing integral cooling passageways, vacuum guard, and internal thermocouples. The coolant enters at the middle of the holder 42 and exits at both ends to maintain symmetry. The cooling channels proved vacuum-tight under repeated cryogenic cycling and baking. FIG. 11 is a close up of the machined in magnet holder with magnet monolith 43 and magnet holder 42. FIG. 12 shows the dowel pin holes 44 with visual of the copper shims 45, for magnet adjusting. Dowel pin holes are located on the magic finger block and are used for corrector magnets.

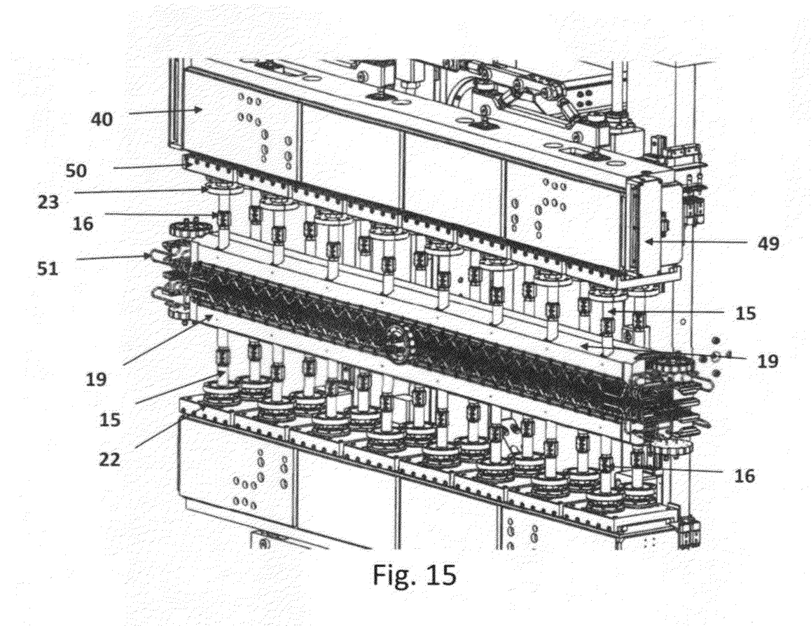

The final figure, FIG. 15 is an overview of the overall mechanical vacuum girder design with associated parts. In vacuum Girders with the required structural rigidity for the UHV magnet arrays required an impractically large vacuum vessel so it was decided to break up the magnet support girders in two parts. The girder design includes the IVU subgirder assembly 50, precision linear encoder 49 for detection of environmentally induced changes that could not be detected by internally mounted encoders. Also seen is the in vacuum girder 19, overall magnet array 52, which includes all accompanying magnets, and cooling system 51, comprised of copper piping. Visualization can be made, incorporating previously listed figures, of the girder 40, hanger shim 22, hanger weldment 23, hanger rods 15 and hanger rod collar 16.

What is claimed is:

1. A system of support girders comprising:
(a) rigid outer support girders;
(b) stainless steel posts between the out-of-vacuum and in-vacuum girders;
(c) precision linear encoders;
(d) two spherical joints per hanger;
(e) platen support rods;
(f) inner threads into the girder;
(g) split coupling.

2. The apparatus of claim 1 wherein the outer support girders are driven by two lead screws.

3. The apparatus of claim 1 wherein said stainless steel posts are affixed between the out-of vacuum and in-vacuum girders in order to provide overall rigidity needed to maintain straightness and flatness needed of the magnet modules.

4. The apparatus of claim 3 wherein magnet modules consist of a range of magnet gaps and varying attractive magnetic forces.

5. The apparatus of claim 1 wherein said linear encoders are mounted to said outer girders.

6. The apparatus of claim 5 wherein said linear encoders are mounted in such a way as to detect environmentally induced changes occurring between the outer girder and the magnet gap, which could not be detected by conventional means.

7. The apparatus of claim 5 wherein said linear encoders provide position feedback.

8. The apparatus of claim 1 wherein the spherical joints consist of:
(h) two hanger rods;
(i) a hanger rod collar;
(j) torque coupling screws.

9. The apparatus of claim 8 wherein said hanger rod collar allows for separation of the hanger rods for easy movement and separation.

10. The apparatus of claim 1 wherein platten support rods contain hanger heating components.

11. The apparatus of claim 10 wherein said hanger heating components control the temperature of each post independently, using:
(k) three heaters per unit;
(l) resistor pad;
(m) probe;
(n) controller.

12. The apparatus of claim 11 wherein said probe mounted to each post monitors the temperature, independent from other posts.

13. The apparatus of claim 11 wherein said controller maintains precise temperature control within 0.1 degree Celsius.

14. The apparatus of claim 1 wherein platten support rods are placed within the platten support assembly as a means of stability.

15. The apparatus of claim 1 wherein inner threads are attached within the out-of-vacuum girder.

16. The apparatus of claim 15 wherein said threads are attached as means of support and stability.

17. The apparatus of claim 1 wherein split coupling is seen in the design of platten support rods.

18. The apparatus of claim 18 wherein split coupling is synonymous for hanger rod collar.
